(19) United States
(12) Patent Application Publication
(10) Pub. No.: US 2025/0081636 A1
(43) Pub. Date: Mar. 6, 2025

(54) BACKSIDE ILLUMINATED IMAGE SENSOR AND METHOD OF MANUFACTURING SAME

(71) Applicant: DB HiTek Co., Ltd., Bucheon-si (KR)

(72) Inventor: Chang Hun HAN, Icheon-si (KR)

(21) Appl. No.: 18/493,120

(22) Filed: Oct. 24, 2023

(30) Foreign Application Priority Data
Aug. 30, 2023 (KR) 10-2023-0114295

(51) Int. Cl. H01L 27/146

(52) U.S. Cl. CPC H10F 39/199; H10F 39/024; H10F 39/8053; H10F 39/8063; H10F 39/811

(57) ABSTRACT

Proposed are a backside illuminated image sensor and a method of manufacturing the same and, more particularly, to a backside illuminated image sensor and a method of manufacturing the same for aligning a color filter part and a lens part formed on a bottom side of a substrate in the correct position by forming one or more align keys extending from a top side of the substrate to be adjacent to the bottom side within a peripheral area.

### CROSS REFERENCE TO RELATED APPLICATION

The present application claims priority to Korean Patent Application No. 10-2023-0114295, filed Aug. 30, 2023, the entire contents of which is incorporated herein for all purposes by this reference.

### BACKGROUND OF THE INVENTION

### Field of the Invention

The present disclosure relates to a backside illuminated image sensor and a method of manufacturing the same and, more particularly, to a backside illuminated image sensor and a method of manufacturing the same for aligning a color filter part and a lens part formed on a bottom side of a substrate in the correct position by forming one or more align keys extending from a top side of the substrate to be adjacent to the bottom side within a peripheral area.

### Description of the Related Art

An image sensor is a video imaging device component that generates images in mobile phone cameras, etc., and can be classified into charge-coupled device (CCD) image sensors and complementary metal-oxide-semiconductor (CMOS) image sensors depending on the production process and application method. Among them, the CMOS image sensors are widely used in the general semiconductor chip manufacturing process due to their excellent integration competitiveness, economic feasibility, and ease of connection with peripheral chips.

A conventional CMOS image sensor includes a wiring part, a color filter part, and a lens part sequentially stacked on the top side of a silicon wafer. However, in an image sensor with this structure, the amount of incident light incident on a light receiving element may be reduced due to metal wires in the wiring part. Accordingly, a so-called backside illuminated CMOS image sensor (BIS) is being developed, which has a structure in which a wiring part is disposed on the top side of the substrate, and the color filter part and the lens part are disposed on the bottom side of the substrate.

FIG. 1 is a cross-sectional view showing a conventional backside illuminated image sensor.

Hereinafter, the structure and problems of a conventional backside illuminated image sensor 9 will be described with reference to the attached drawings.

Referring to FIG. 1, a substrate 901 is formed in the conventional backside illuminated image sensor 9, and the substrate 901 has a top side 9011 and a bottom side 9013. In addition, in a pixel area P, a color filter part 910 is formed on the bottom side 9013 of the substrate 901, a planarization layer 930 is formed on the color filter part 910, and a microlens 950 is formed on the planarization layer 930 sequentially. A device isolation region 970 may be formed on the boundary side of each unit pixel area P1 and on the top side 9011 of the substrate 901. In addition, an align key 990 is formed on the top side 9011 of the substrate 901 in a peripheral area S. The align key 990 extends from the top side 9011 of the substrate 910 to the bottom side 9013, and may extend to a depth approximately similar to that of the device isolation region 970. The align key 990 is a standard component for aligning individual color filters and microlenses to the correct positions in the process for forming the color filter part 910 and microlens 950.

In recent image sensors, the thickness of the substrate 901 is increasing to improve sensitivity. The problem is that the thicker the substrate, the weaker the signal becomes, and thus difficulties arise in confirming photo alignment when the photo alignment needs to be confirmed using the align key 990 in the photo process for forming the microlens 950.

In order to solve the above-described problems, the inventor of the present disclosure proposes a backside illuminated image sensor with a novel align key structure and a method of manufacturing the image sensor, which will be described in detail later.

### Documents of Related Art

(Patent Document 0001) Korean Patent No. 10-0660549 “IMAGE SENSOR AND METHOD OF MANUFACTURING SAME”

### SUMMARY OF THE INVENTION

The present disclosure has been made to solve the problems of the related art, and an objective of the present disclosure is to provide a backside illuminated image sensor and a method of manufacturing the same, which enable easy photo alignment confirmation even if a substrate is formed to a certain thickness or greater by ensuring that align keys extend from the top side of the substrate to the side adjacent to the bottom side.

An objective of the present disclosure is to provide a backside illuminated image sensor and a method of manufacturing the same, which enable photo alignment confirmation in both the x-axis and y-axis directions by having an align key including a first region extending laterally and a second region extending longitudinally.

An objective of the present disclosure is to provide a backside illuminated image sensor and a method of manufacturing the same, which enable more precise photo alignment confirmation by additionally forming a second align key that surrounds a first align key but does not contact the first align key.

An objective of the present disclosure is to provide a backside illuminated image sensor and a method of manufacturing the same, which enable easy detection of signals through reflection of incident light by ensuring that an align key includes a metal film.

An objective of the present disclosure is to provide a backside illuminated image sensor and a method of manufacturing the same in which one end of an align key including a metal film is formed within a lower insulating film, so that the metal film is formed together in a contact plug forming process, thereby eliminating the need for additional processes.

The present disclosure may be implemented by the embodiments having the following configuration in order to achieve the above-described objectives.

According to an embodiment of the present disclosure, there is provided a backside illuminated image sensor, including: a substrate having a top side and a bottom side; a photoelectric conversion element in the substrate within a pixel area; a wiring region disposed on the top side of the substrate; a color filter part disposed on the bottom side of the substrate within the pixel area; a planarization layer disposed on the color filter part; a lens part disposed on the planarization layer; and an align key extending from the top side to a side adjacent to the bottom side of the substrate within a peripheral area.

According to another embodiment of the present disclosure, in the backside illuminated image sensor, the align key may extend from the top side of the substrate to a depth of approximately 60% to 90% of a total depth of the substrate.

According to still another embodiment of the present disclosure, in the backside illuminated image sensor, as the align key may extend from the top side to the bottom side of the substrate, a width of an inner wall of the align key becomes narrower.

According to still another embodiment of the present disclosure, in the backside illuminated image sensor, the align key may include: a first region extending in a lateral direction; and a second region extending in a longitudinal direction.

According to still another embodiment of the present disclosure, in the backside illuminated image sensor, the first region may be provided in a set of two, with the two first regions being spaced apart from each other longitudinally, and the second region may be provided in a set of two, with the two second regions being spaced apart from each other laterally.

According to still another embodiment of the present disclosure, in the backside illuminated image sensor, the align key may have a substantially rectangular planar shape.

According to still another embodiment of the present disclosure, in the backside illuminated image sensor, the align key may include: a first align key having a laterally extending region and a longitudinally extending region; and a second align key having a laterally extending region and a longitudinally extending region to surround the first align key.

According to still another embodiment of the present disclosure, in the backside illuminated image sensor, the align key may comprises an insulating film gap-filled within a via hole formed from the top side to the bottom side of the substrate.

According to still another embodiment of the present disclosure, in the backside illuminated image sensor, the align key may include: an insulating film; and a metal film on the insulating film.

According to still another embodiment of the present disclosure, a backside illuminated image sensor according to the present disclosure includes: a substrate having a top side and a bottom side; a photoelectric conversion element in the substrate within a pixel area; a wiring region disposed on the top side of the substrate; a color filter part disposed on the bottom side of the substrate within the pixel area; a planarization layer disposed on the color filter part; a lens part disposed on the planarization layer; and an align key having a first end in the wiring region and a second end in the substrate within a peripheral area.

According to still another embodiment of the present disclosure, in the backside illuminated image sensor, the wiring region may include: wiring layers having a multi-layer metal film structure and connected to each other by contact plugs; and a lower insulating layer surrounding the wiring layers.

According to still another embodiment of the present disclosure, in the backside illuminated image sensor, the align key may have an end within the lower insulating layer.

According to still another embodiment of the present disclosure, in the backside illuminated image sensor, the align key may have an end substantially at a same height or depth as an upper end of one of the wiring layers closest to the top side of the substrate.

According to still another embodiment of the present disclosure, in the backside illuminated image sensor, the align key may comprise a metal film gap-filled in an insulating film which is deposited in a via hole formed from a side of the lower insulating layer to a side adjacent to the bottom side of the substrate.

According to still another embodiment of the present disclosure, in the backside illuminated image sensor, wherein the metal film may be formed together during a process of forming the contact plugs for electrical connection of the wiring layers.

According to an embodiment of the present disclosure, there is provided a method of manufacturing a backside illuminated image sensor, the method including: forming a photoelectric conversion element and a device isolation region in a substrate within a pixel area; forming a wiring region by alternately stacking a wiring layer and a lower insulating layer on a top side of the substrate; forming an align key in the substrate within a peripheral area; and forming a color filter part, a planarization layer, and a lens part on a bottom side of the substrate within the pixel area, wherein the align key may have an upper end adjacent to the bottom side of the substrate.

According to another embodiment of the present disclosure, in the method of manufacturing a backside illuminated image sensor, the forming the align key may include: forming a via hole by etching the top side of the substrate; and gap-filling an insulating film in the via hole.

According to still another embodiment of the present disclosure, in the method of manufacturing a backside illuminated image sensor, the forming the align key may include: forming a via hole by etching the top side of the substrate; depositing an insulating film along an inner wall of the via hole; and gap-filling a metal film in the insulating film.

According to still another embodiment of the present disclosure, in the method of manufacturing a backside illuminated image sensor, the forming the align key may include: forming a via hole by etching a lower insulating layer and the top side of the substrate; depositing an insulating film along an inner wall of the via hole; and gap-filling a metal film in the insulating film, wherein the metal film may be formed together during a process of forming a contact plug for electrical connection of the wiring layer.

According to still another embodiment of the present disclosure, the method of manufacturing a backside illuminated image sensor may further include: forming a device isolation region that extends to a predetermined depth from the top side to the bottom side of the substrate, wherein the align key may have an upper end closer to the bottom side of the substrate than an upper end of the device isolation region.

The present disclosure has the following effects by the above configurations.

According to the present disclosure, it is possible to easily confirm photo alignment even if a substrate is formed to a certain thickness or greater by ensuring that align keys extend from the top side of the substrate to the side adjacent to the bottom side.

In addition, according to the present disclosure, it is possible to confirm photo alignment in both the x-axis and y-axis directions by having an align key including a first region extending laterally and a second region extending longitudinally.

In addition, according to the present disclosure, it is possible to more precisely confirm photo alignment by additionally forming a second align key that surrounds a first align key but does not contact the first align key.

In addition, according to the present disclosure, it is possible to easily detect signals through reflection of incident light by ensuring that an align key includes a metal film.

In addition, according to the present disclosure, one end of an align key including a metal film is formed within a lower insulating film, so that the metal film is formed together in a contact plug forming process, thereby eliminating the need for additional processes.

Meanwhile, it should be added that even if effects are not explicitly mentioned herein, the effects described in the following specification expected by the technical features of the present disclosure and their potential effects are treated as if they were described in the specification of the present disclosure.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a cross-sectional view showing a conventional backside illuminated image sensor;

FIG. 2 is a cross-sectional view of a backside illuminated image sensor according to an embodiment of the present disclosure;

FIG. 3 is a plan view of an align key according to an embodiment of the present disclosure;

FIG. 4 is a cross-sectional view of a backside illuminated image sensor according to another embodiment of the present disclosure;

FIG. 5 is a cross-sectional view of a backside illuminated image sensor according to still another embodiment of the present disclosure; and

FIGS. 6 to 12 are cross-sectional views showing a method of manufacturing a backside illuminated image sensor according to an embodiment of the present disclosure.

### DETAILED DESCRIPTION OF THE INVENTION

Hereinafter, embodiments of the present disclosure will be described in more detail with reference to the accompanying drawings. The embodiments of the present disclosure may be modified in various forms, and the scope of the present disclosure should not be construed as being limited to the following embodiments, but should be construed based on the matters described in the claims. In addition, these embodiments are only provided for reference in order to more completely explain the present disclosure to those of ordinary skill in the art.

The terms first, second, third, etc. may be used to describe various items such as various components, regions and/or parts. However, the items are not limited by these terms.

In addition, it should be noted that, where certain embodiments are otherwise feasible, certain process sequences may be performed other than those described below. For example, two processes described in succession may be performed substantially simultaneously or in the reverse order.

In the drawing, the x-axis direction is described as the “lateral direction” and the y-axis direction is described as the “longitudinal direction”.

In a backside illuminated image sensor 1 according to the present disclosure, a pixel area P and a peripheral area S may be formed. The pixel area P is an area that absorbs light incident on the bottom side of a first substrate 101 from the outside, and the peripheral area S is an area forming the periphery of the pixel area P. The pixel area P may include a plurality of unit pixel areas P1. In the peripheral area S, a PAD part (not shown) may be formed to electrically connect to an external terminal.

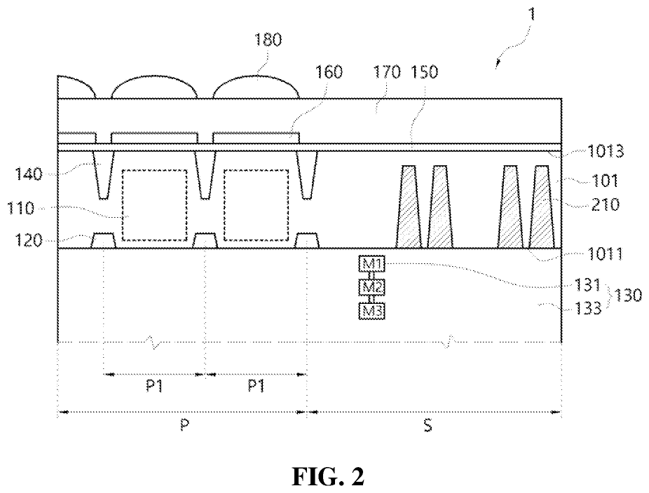

FIG. 2 is a cross-sectional view of a backside illuminated image sensor according to an embodiment of the present disclosure.

Hereinafter, a backside illuminated image sensor 1 according to an embodiment (first embodiment) of the present disclosure will be described in detail with reference to the attached drawings.

Referring to FIG. 2, the present disclosure relates to a backside illuminated image sensor 1 and a method of manufacturing the same and, more particularly, to a backside illuminated image sensor 1 and a method of manufacturing the same for aligning a color filter part 160 and a lens part 180 formed on a bottom side 1013 of a substrate 101 in the correct position by forming one or more align keys 210 extending from a top side 1011 of the substrate 101 to be adjacent to the bottom side 1013 within the peripheral area S.

The structure of a backside illuminated image sensor 1 according to an embodiment of the present disclosure will be described. First, a substrate 101 is formed. The substrate 101 has a top side 1011 and a bottom side 1013. The substrate 101 may include, for example, an epitaxial substrate or a bulk substrate. In addition, a photoelectric conversion element 110 is formed within the substrate 101. The photoelectric conversion element 110 may be formed for each individual unit pixel area P1 forming the pixel area P. The photoelectric conversion element 110 may be made of any of a variety of known or to be known configurations, for example, photo diode, photo gate, photo transistor, etc., and there is no particular limitation thereon. The photoelectric conversion element 110 may be formed by ion implanting a second conductivity type (N-type) impurity into one side of the first conductivity type (P-type) substrate 101, but there is no particular limitation thereon. In addition, one or more transistors (not shown) electrically connected to the photoelectric conversion element 110 may be formed.

Within the pixel area P, a device isolation region 120 is formed in the substrate 101. The device isolation region 120 is, for example, a shallow trench isolation (STI) region, is formed at the border of adjacent unit pixel areas P1, and may extend from the top side 1011 of the substrate 101 to the bottom side 1013 by a predetermined depth.

In addition, a wiring region 130 may be formed on the top side 1011 of the substrate 101. The wiring region 130 may include a wiring layer 131 and a lower insulating layer 133.

The wiring layer 131 is, for example, composed of a single metal or an alloy film containing different types of metals, and preferably includes, for example, an aluminum (Al) film. In addition, the wiring layer 131 may be formed in a multi-layer structure M1, M2, and M3 within the lower insulating layer 133.

The lower insulating layer 133 includes, for example, an insulating material, such as a silicon oxide film, and is composed of an insulating film that is repeatedly stacked with the wiring layer 131. In addition, the wiring layer 131 of one layer may be electrically connected to the wiring layer 131 of another adjacent layer through a contact plug. One wiring layer 131 may be electrically connected to a transistor through the contact plug. The contact plug may be formed in the lower insulating layer 133 by a damascene process. In order to electrically connect the vertically stacked wiring layers 131, the contact plug may be made of a conductive material, for example, one or more selected from a polycrystalline silicon film doped with impurity ions, a metal, or an alloy film mixed with different metals.

In addition, the lower insulating layer 133 may be formed of any one oxide film selected from BPSG, PSG, BSG, USG, TEOS, or HDP, or may be formed as a stacked film of two or more layers thereof. The lower insulating layer 133 may be planarized after deposition, for example, through a CMP process.

A deep trench isolation (DTI) region 140 may be formed within the substrate 101 in the pixel area P. The DTI region 140 is configured to extend to a predetermined depth from the bottom side 1013 toward the top side 1011 of the substrate 101, and is preferably formed at the border of adjacent unit pixel areas P1. In addition, the DTI region 140 may be formed by gap-filling an oxide film selected from, for example, BPSG, PSG, BSG, USG, TEOS, or HDP, but is not limited thereto.

An interlayer insulating film 150 may be formed on the bottom side 1013 of the substrate 101. The interlayer insulating film 150 may, for example, be composed of an oxide film.

On the bottom side 1013 of the substrate 101 or the interlayer insulating film 150 in the pixel area P, a color filter part 160 may be formed. The light incident through the lens part 180, which will be described later, is selected so that only the necessary color light is selected by corresponding color filters R, G, and B of the color filter part 160, and the selected color light is incident on the photoelectric conversion element 110 of the corresponding unit pixel area P1. The formation process of the color filter part 160 will be explained. As an example, a red color filter may be formed by applying a red photoresist on the bottom side 1013 of the substrate 101 and exposing and developing the red photoresist, and a green color filter may be formed by applying a green photoresist on a protective film on which the red color filter is formed, and exposing and developing the green photoresist. Afterwards, a blue color filter may be formed by applying a blue photoresist and exposing and developing the blue photoresist.

A planarization layer 170 may be formed on the color filter part 160. The planarization layer 170 may include, for example, a silicon oxide film.

The lens part 180 is formed on the planarization layer 170, and the lens part 180 may include a plurality of microlenses ML so that the light incident on the bottom side 1013 of the substrate 101 is focused on the photoelectric conversion element 110 in the corresponding unit pixel area P1. The lens part 180 may be formed in the pixel area P.

In addition, an align key 210 may be formed within the substrate 101 in the peripheral area S. The align key 210 may extend from the top side 1011 of the substrate 101 to the side adjacent to the bottom side 1013. As an example, the align key 210 may extend from the top side 1011 of the substrate 101 by a distance of less than 1 μm from the bottom side 1013. As another example, the align key 210 may be formed to extend from the top side 1011 of the substrate 101 to a depth of about 60 to 90% of the total depth of the substrate 101.

Hereinafter, in addition to the structure and problems of a conventional backside illuminated image sensor 9, a backside illuminated image sensor 1 according to an embodiment of the present disclosure will be described in detail.

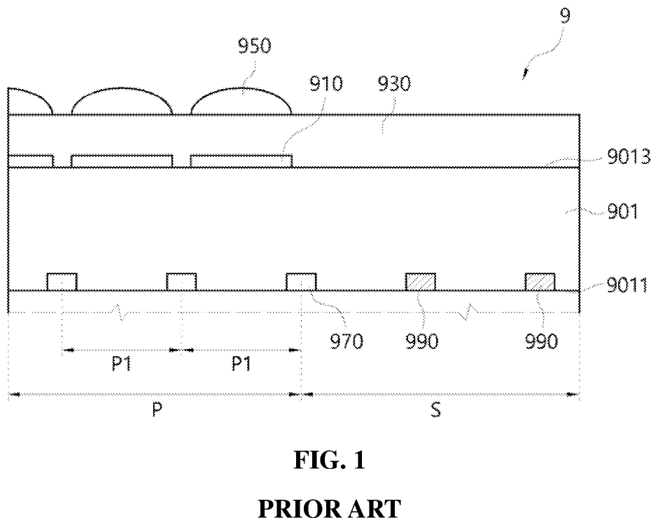

Referring to FIG. 1, a substrate 901 is formed in the conventional backside illuminated image sensor 9, and the substrate 901 has a top side 9011 and a bottom side 9013. In addition, in a pixel area P, a color filter part 910 is formed on the bottom side 9013 of the substrate 901, a planarization layer 930 is formed on the color filter part 910, and a microlens 950 is formed on the planarization layer 930 sequentially. A device isolation region 970 may be formed on the boundary side of each unit pixel area P1 and on the top side 9011 of the substrate 901. In addition, an align key 990 is formed on the top side 9011 of the substrate 901 in a peripheral area S. The align key 990 extends from the top side 9011 of the substrate 910 to the bottom side 9013, and may extend to a depth approximately similar to that of the device isolation region 970. The align key 990 is a standard component for aligning individual color filters and microlenses to the correct positions in the process for forming the color filter part 910 and microlens 950.

In image sensors of late, the thickness of the substrate 901 is increasing to improve sensitivity. The problem is that the thicker the substrate, the weaker the signal becomes, and thus difficulties arise in confirming photo alignment when the photo alignment needs to be confirmed using the align key 990 in the photo process for forming the microlens 950.

Referring to FIG. 2, in order to solve the above-described problems, in the backside illuminated image sensor 1 according to the embodiment of the present disclosure, the align key 210 is formed from the top side 1011 of the substrate 101 to the side adjacent to the bottom side 1013. As an example, it is preferable that the align key 210 is formed to extend to a position deeper than the device isolation region 120 within the substrate 101 or to the side adjacent to the bottom side 1013 of the substrate 101 compared to the device isolation region 120. As previously described, the align key 210 may extend from the top side 1011 of the substrate 101 by a distance of less than 1 μm from the bottom side 1013.

In addition, the align key 210 may be formed so that the inner wall thereof becomes narrower as the align key 210 extends from the top side 1011 of the substrate 101 toward the bottom side 1013. Thus, the upper side of the align key 210 may be formed to have the narrowest shape. On the contrary, the align key 210 may be formed to have a substantially uniform width as the align key 210 extends from the top side 1011 of the substrate 101 toward the bottom side 1013. The align key 210 may be configured such that an insulating film such as an oxide film is gap-filled within a via hole.

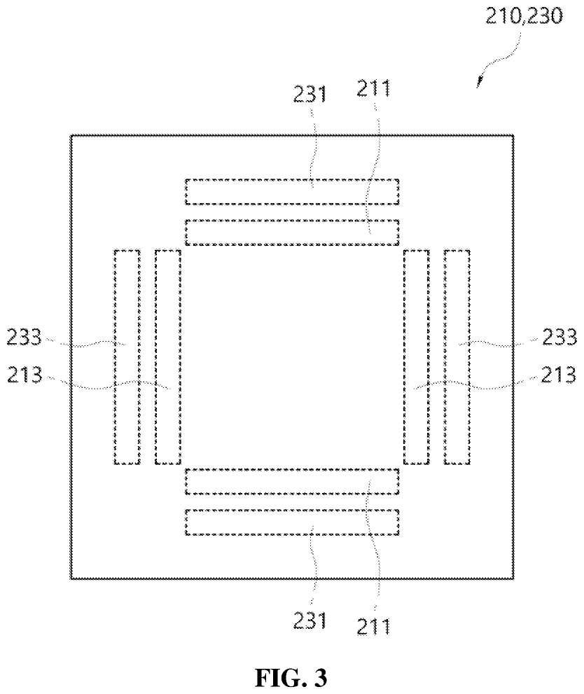

FIG. 3 is a plan view of an align key according to an embodiment of the present disclosure.

Referring to FIG. 3, the align key 210 may include a first region 211 extending laterally and a second region 213 extending longitudinally. At this time, a pair of the first regions 211 may be formed to be spaced apart from each other in the longitudinal direction, and a pair of second regions 213 may be formed to be spaced apart from each other in the lateral direction. As an example, the align key 210 including a pair of the first regions 211 and a pair of second regions 213 may have a substantially rectangular planar shape. In addition, the ends of the first region 211 and the adjacent second region 213 may be formed to contact each other or not to contact each other, and there is no particular limitation thereon. In this way, it is possible to confirm the photo alignment in the y-axis direction by means of the first region 211, and the photo alignment in the x-axis direction is possible by means of the second region 213.

An additional align key 230 may be formed to surround the align key 210. At this time, the previously-described align key 210 is referred to as the “first align key 210”, and the additional align key 230 is referred to as the “second align key 230”. Similar to the first align key 210, the second align key 230 may also have a pair of first regions 231 spaced apart from each other longitudinally and extending along the lateral direction, and a pair of second regions 233 spaced apart from each other laterally and extending along the longitudinal direction. At this time, it is preferable that the first region 231 of the second align key 230 is spaced apart from the first region 211 of the adjacent first align key 210 in the longitudinal direction. Likewise, it is preferable that the second region 233 of the second align key 230 is laterally spaced from the second region 213 of the adjacent first align key 210. The ends of the first region 231 and the second region 233 may be formed to contact each other or not to contact each other.

In addition, when necessary, a third align key may be formed to surround the second align key 230, but there is no particular limitation thereon. At this time, the third align key may also have a rectangular planar shape like the second align key 230.

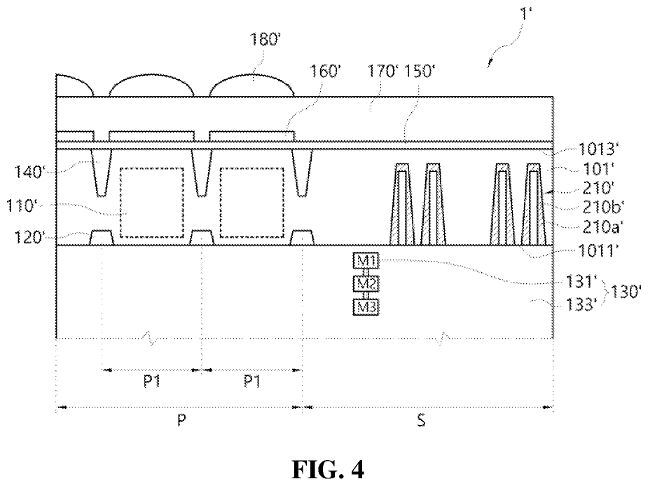

FIG. 4 is a cross-sectional view of a backside illuminated image sensor according to another embodiment of the present disclosure.

Hereinafter, a backside illuminated image sensor 1′ according to another embodiment (second embodiment) of the present disclosure will be described with reference to the attached drawings. Since the image sensor 1′ to be described differs from the above-described image sensor 1 only in the gap-filling nature of the align key, description of the remaining configuration will be omitted.

Referring to FIG. 4, in the backside illuminated image sensor 1′ according to another embodiment of the present disclosure, an align key 210′ is formed from a top side 1011′ of a substrate 101′ to the side adjacent to a bottom side 1013′. As an example, it is preferable that the align key 210′ is formed to extend to a position deeper than the device isolation region 120′ within the substrate 101′ or to the side adjacent to the bottom side 1013′ of the substrate 101′ compared to the device isolation region 120′. As previously described, the align key 210′ may extend from the top side 1011′ of the substrate 101′ by a distance of less than 1 μm from the bottom side 1013′.

In addition, the align key 210′ may be formed so that the inner wall thereof becomes narrower as the align key 210′ extends from the top side 1011′ of the substrate 101′ toward the bottom side 1013′. Thus, the upper side of the align key 210′ may be formed to have the narrowest shape. On the contrary, the align key 210′ may be formed to have a substantially uniform width as the align key 210′ extends toward the bottom side 1013′. The align key 210′ may be formed by depositing an insulating film 210a′, such as an oxide film, along the inner wall of a via hole, and gap-filling a metal film 210b′ on the insulating film 210a′ before performing a CMP process. Thus, the align key 210′ may be formed of a double layer of an insulating film 210a′ and a metal film 210b′. At this time, the metal film 210b′ may include, for example, tungsten (W). By forming the metal film 210b′ within the align key 210′ in this way, signal detection is possible through reflection of light incident on the bottom side 1013′ of the substrate 101′, making photo alignment confirmation relatively easy.

In addition, since the align key 210′ may have substantially the same planar structure as the align key 210 according to the above-described embodiment, detailed description thereof will be omitted.

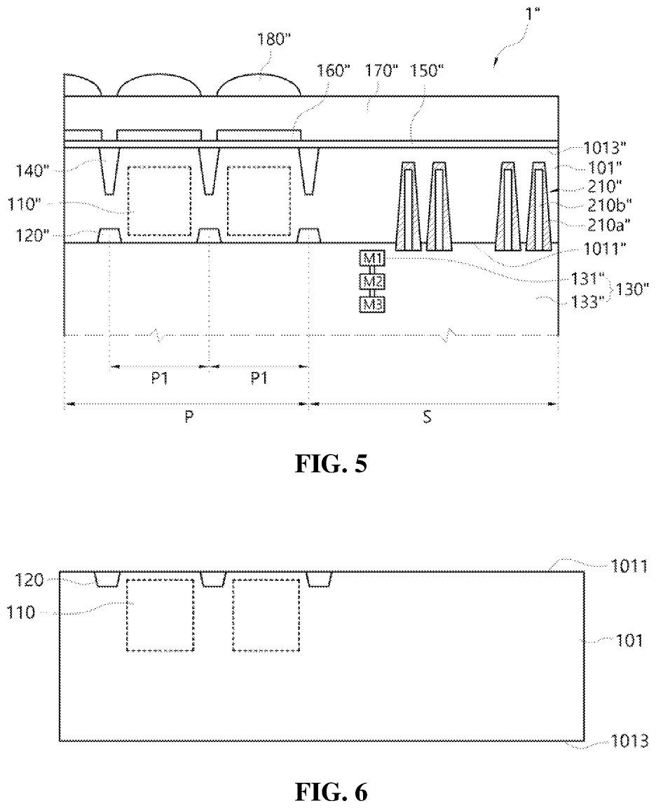

FIG. 5 is a cross-sectional view of a backside illuminated image sensor according to still another embodiment of the present disclosure.

Hereinafter, a backside illuminated image sensor 1″ according to still another embodiment (third embodiment) of the present disclosure will be described with reference to the attached drawings. Since the image sensor 1″ to be described differs from the above-described image sensor 1′ only in the gap-filling nature of the align key, description of the remaining configuration will be omitted.

Referring to FIG. 5, in the backside illuminated image sensor 1″ according to another embodiment of the present disclosure, an align key 210″ is formed from a top side 1011″ of a substrate 101″ to the side adjacent to a bottom side 1013″. As an example, it is preferable that the align key 210″ is formed to extend to a position deeper than the device isolation region 120″ within the substrate 101″ or to the side adjacent to the bottom side 1013″ of the substrate 101″ compared to the device isolation region 120″. As previously described, the align key 210″ may extend from the top side 1011″ of the substrate 101″ by a distance of less than 1 μm from the bottom side 1013″.

In addition, the align key 210″ may be formed so that the inner wall thereof becomes narrower as the align key 210″ extends from the top side 1011″ of the substrate 101″ toward the bottom side 1013″ or has a substantially uniform width. The align key 210″ may be formed by depositing an insulating film 210a″, such as an oxide film, along the inner wall of a via hole, and gap-filling a metal film 210b″ on the insulating film 210a″ before performing a CMP process. Thus, the align key 210″ may be formed of a double layer of an insulating film 210a″ and a metal film 210b″. At this time, the metal film 210b″ may include, for example, tungsten (W). By forming the metal film 210b″ within the align key 210″ in this way, signal detection is possible through reflection of light incident on the bottom side 1013″ of the substrate 101″, making photo alignment confirmation relatively easy.

At this time, the align key 210″ may be formed so that the lower end thereof on the top 1011″ side of the substrate 101″ extends to a lower insulating layer 133″ of a wiring region 130″. As an example, the lower end of the align key 210″ may be formed at substantially the same height or depth as the upper end of a wiring layer (for example, M1; 131″) closest to the top side 1011″ of the substrate 101″. That is, when forming the metal film 210b″ of the align key 210″, additional processes may be avoided by forming the metal film 210b″ together in a contact plug formation process instead of performing a separate gap fill process to form the metal film 210b″. As an example, during the contact plug formation process for electrical connection between a readout circuit (not shown) consisting of transfer transistor, reset transistor, etc. and the wiring layer M1, the gap fill process for forming the metal film 210b″ may be performed together.

In addition, since the align key 210″ may have substantially the same planar structure as the align key 210 according to the above-described embodiment, detailed description thereof will be omitted.

FIGS. 6 to 12 are cross-sectional views showing a method of manufacturing a backside illuminated image sensor according to an embodiment of the present disclosure.

Referring to FIG. 6, first, a photoelectric conversion element 110 and a device isolation region 120 are formed within a substrate 101. As previously mentioned, the photoelectric conversion element 110 may be formed, for example, by ion implanting impurities of the second conductivity type into the substrate 101 of the first conductivity type. The device isolation region 120 may be formed through an STI process. The device isolation region 120 may be formed at a predetermined depth from a top side 1011 to a bottom side 1013 of the substrate 101. Both the photoelectric conversion element 110 and the device isolation region 120 may be formed within a pixel area P.

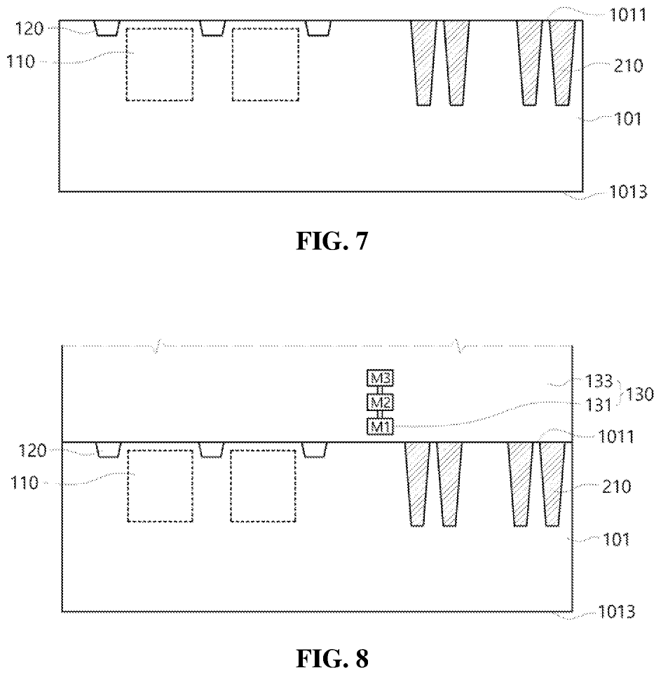

Thereafter, referring to FIG. 7, an align key 210 may be formed within the substrate 101 in a peripheral area S. As a first embodiment, the align key 210 may be formed by etching the top side 1011 of the substrate 101 to a predetermined depth to form a via hole, and then gap-filling the insulating film within the via hole. As a second embodiment, the align key 210′ may be formed by depositing an insulating film 210a′ in the via hole and then gap-filling a metal film 201b′ on the insulating film 210a′ (see FIG. 4). In addition, as a third embodiment, the align key 210″ may be formed so that the lower end thereof extends into a lower insulating layer 133″ of a wiring region 130″ (see FIG. 5). At this time, the lower end of the align key 210″ may be formed at substantially the same height or depth as the upper end of a first metal M1. According to the third embodiment, there is an advantage in that the metal film 210b″ is formed together in a contact plug formation process without a separate gap fill process for forming the metal film 210b″.

Referring to FIG. 8, a wiring region 130 may then be formed on the top side 1011 of the substrate 101. The wiring region 130 may be formed by alternately stacking a wiring layer 131 and a lower insulating layer 133. The wiring layer 131 may include, for example, a first metal M1, a second metal M2, and a third metal M3, etc., but there is no particular limitation thereon.

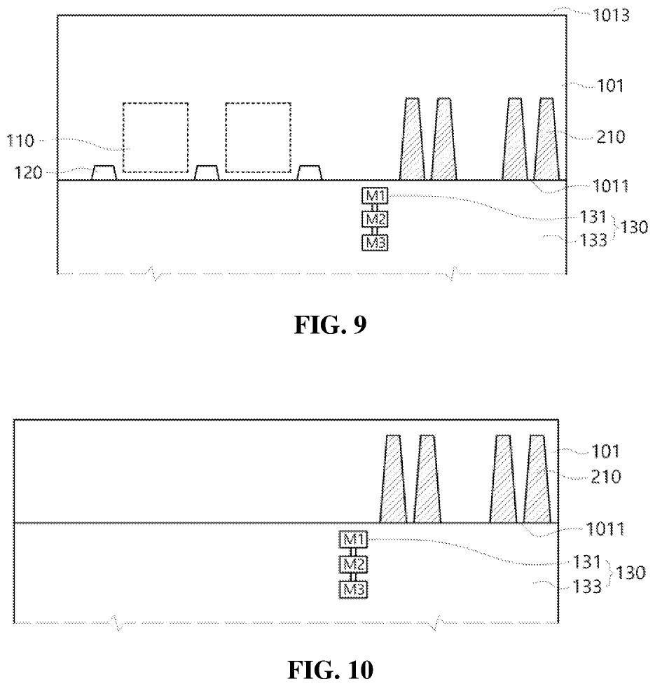

Referring to FIG. 9, the substrate 101 is then flipped upside down so that the bottom side 1013 is placed on top.

Thereafter, referring to FIG. 10, the bottom side 1013 of the substrate 101 is partially removed. For example, a back grinding process or an etch-back process may be performed for thinning of the bottom side 1013 of the substrate 1011.

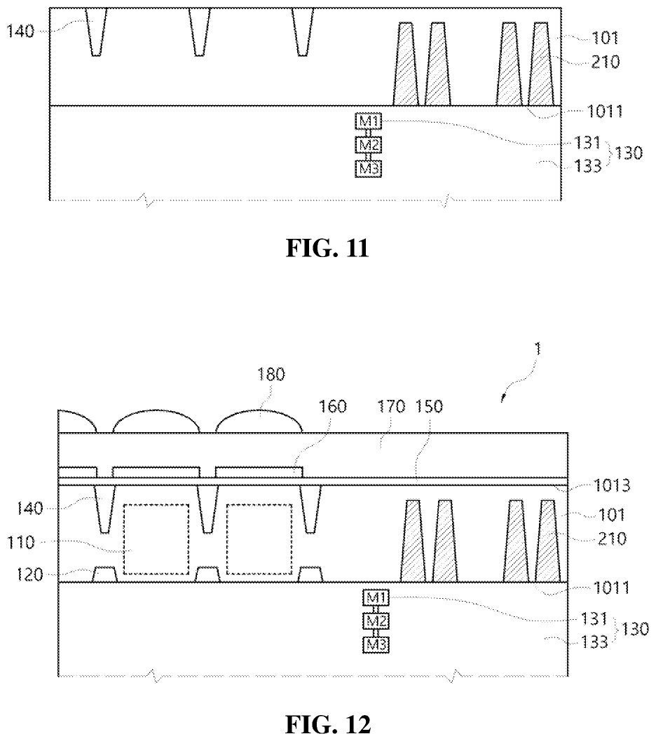

Referring to FIG. 11, in a subsequent process, a DTI region 140 extending from the bottom side 1013 of the substrate 101 toward the top side 1011 may be formed. The DTI region 140 may be formed by performing an etching process using a silver mask pattern (not shown) and then depositing an insulating material. In addition, an interlayer insulating film 150 may be formed on the bottom side 1013 of the substrate 101.

Referring to FIG. 12, a color filter part 160 may then be formed on the interlayer insulating film 150. As an example, the color filter part 160 may form a red color filter by applying a red photoresist on the bottom side 1013 of the substrate 101 and exposing and developing the red photoresist, and a green color filter by applying a green photoresist on a protective film on which the red color filter is formed, and exposing and developing the green photoresist. Afterwards, the color filter part 160 may form a blue color filter by applying a blue photoresist and exposing and developing the blue photoresist.

A planarization layer 170 may be formed on the color filter part 160. The planarization layer 170 may include, for example, a silicon oxide film. In addition, a lens part 180 is formed on the planarization layer 170, and the lens part 180 may include a plurality of microlenses ML so that the light incident on the bottom side 1013 of the substrate 101 is focused on the photoelectric conversion element 110 in a corresponding unit pixel area P1. When forming the lens part 180, photo alignment may be confirmed because it is possible to confirm the photo alignment in the y-axis direction by means of a first region 211 of the align key 210 and to confirm the photo alignment in the x-axis direction by means of a second region 213 of the align key 210.

The above detailed description is illustrative of the present disclosure. In addition, the above description shows and describes preferred embodiments of the present disclosure, and the present disclosure can be used in various other combinations, modifications, and environments. That is, changes or modifications are possible within the scope of the concept of the disclosure disclosed herein, the scope equivalent to the written disclosure, and/or within the scope of skill or knowledge in the art. The above-described embodiment describes the best state for implementing the technical idea of the present disclosure, and various changes required in the specific application field and use of the present disclosure are possible. Accordingly, the detailed description of the present disclosure is not intended to limit the present disclosure to the disclosed embodiments.

What is claimed is:

1. A backside illuminated image sensor, comprising:
a substrate having a top side and a bottom side;
a photoelectric conversion element in the substrate within a pixel area;
a wiring region disposed on the top side of the substrate;
a color filter part disposed on the bottom side of the substrate within the pixel area;
a planarization layer disposed on the color filter part;
a lens part disposed on the planarization layer; and
an align key extending from the top side to a side adjacent to the bottom side of the substrate within a peripheral area.

2. The backside illuminated image sensor of claim 1, wherein the align key extends from the top side of the substrate to a depth of approximately 60% to 90% of a total depth of the substrate.

3. The backside illuminated image sensor of claim 1, wherein as the align key extends from the top side to the bottom side of the substrate, a width of an inner wall of the align key becomes narrower.

4. The backside illuminated image sensor of claim 1, wherein the align key comprises:
a first region extending in a lateral direction; and
a second region extending in a longitudinal direction.

5. The backside illuminated image sensor of claim 4, wherein the first region is provided in a set of two, with the two first regions being spaced apart from each other longitudinally, and the second region is provided in a set of two, with the two second regions being spaced apart from each other laterally.

6. The backside illuminated image sensor of claim 5, wherein the align key has a substantially rectangular planar shape.

7. The backside illuminated image sensor of claim 1, wherein the align key comprises:
a first align key having a laterally extending region and a longitudinally extending region; and
a second align key having a laterally extending region and a longitudinally extending region to surround the first align key.

8. The backside illuminated image sensor of claim 1, wherein the align key comprises an insulating film gap-filled within a via hole formed from the top side to the bottom side of the substrate.

9. The backside illuminated image sensor of claim 1, wherein the align key comprises:
an insulating film; and
a metal film on the insulating film.

10. A backside illuminated image sensor, comprising:
a substrate having a top side and a bottom side;
a photoelectric conversion element in the substrate within a pixel area;
a wiring region disposed on the top side of the substrate;
a color filter part disposed on the bottom side of the substrate within the pixel area;
a planarization layer disposed on the color filter part;
a lens part disposed on the planarization layer; and
an align key having a first end in the wiring region and a second end in the substrate within a peripheral area.

11. The backside illuminated image sensor of claim 10, wherein the wiring region comprises:
wiring layers having a multi-layer metal film structure and connected to each other by contact plugs; and
a lower insulating layer surrounding the wiring layers.

12. The backside illuminated image sensor of claim 11, wherein the align key has an end within the lower insulating layer.

13. The backside illuminated image sensor of claim 12, wherein the align key has an end substantially at a same height or depth as an upper end of one of the wiring layers closest to the top side of the substrate.

14. The backside illuminated image sensor of claim 12, wherein the align key comprises a metal film gap-filled in an insulating film which is deposited in a via hole formed from a side of the lower insulating layer to a side adjacent to the bottom side of the substrate.

15. The backside illuminated image sensor of claim 14, wherein the metal film is formed together during a process of forming the contact plugs for electrical connection of the wiring layers.

16. A method of manufacturing a backside illuminated image sensor, the method comprising:
forming a photoelectric conversion element and a device isolation region in a substrate within a pixel area;
forming a wiring region by alternately stacking a wiring layer and a lower insulating layer on a top side of the substrate;
forming an align key in the substrate within a peripheral area; and
forming a color filter part, a planarization layer, and a lens part on a bottom side of the substrate within the pixel area,
wherein the align key has an upper end adjacent to the bottom side of the substrate.

17. The method of claim 16, wherein the forming the align key comprises:
forming a via hole by etching the top side of the substrate; and
gap-filling an insulating film in the via hole.

18. The method of claim 16, wherein the forming the align key comprises:
forming a via hole by etching the top side of the substrate;
depositing an insulating film along an inner wall of the via hole; and
gap-filling a metal film in the insulating film.

19. The method of claim 16, wherein the forming the align key comprises:
forming a via hole by etching a lower insulating layer and the top side of the substrate;
depositing an insulating film along an inner wall of the via hole; and
gap-filling a metal film in the insulating film,
wherein the metal film is formed together during a process of forming a contact plug for electrical connection of the wiring layer.

20. The method of claim 16, further comprising:
forming a device isolation region that extends to a predetermined depth from the top side to the bottom side of the substrate,
wherein the align key has an upper end closer to the bottom side of the substrate than an upper end of the device isolation region.
